(19) United States
(12) Patent Application Publication
(10) Pub. No.: US 2025/0132110 A1
(43) Pub. Date: Apr. 24, 2025

(54) KEY CIRCUIT

(71) Applicant: Peratech Electronic Tech Suzhou Co Ltd, Suzhou (CN)

(72) Inventors: Fredrik Jonsson, Gävle (SE); Ce Zhang, Suzhou (CN); Kui Li, Suzhou (CN); Xin Wei, Suzhou (CN)

(73) Assignee: Peratech Electronic Tech Suzhou Co Ltd, Suzhou, JS (CN)

(21) Appl. No.: 18/933,875

(22) Filed: Oct. 31, 2024

(30) Foreign Application Priority Data
Aug. 31, 2023 (CN) 202311111612.3

(51) Int. Cl. H01H 13/81; G06F 3/02

(52) U.S. Cl. CPC H01H 13/81; G06F 3/0202; H01H 2201/036

(57) ABSTRACT

The present application provides a key circuit, wherein the circuit includes: a plurality of keys, a plurality of driving lines, a plurality of induction lines and a control module, wherein the plurality of keys are divided into a plurality of regions according to parameters affecting force and resistance response, and resistance of the keys in each region changes with pressure within the same range; each key is connected to one driving line and one induction line, and keys in the same region are connected to the same induction line; and the plurality of driving lines and the plurality of induction lines are all connected to I/O interfaces of the control module, and are configured to transmit acquired resistance information of corresponding keys to the control module, so as to output control information corresponding to the keys via the control module.

### TECHNICAL FIELD

The present application relates to the field of input devices, and specifically to a key circuit.

### BACKGROUND ART

With regard to keys of a pressure sensor, when a key is pressed down, an upper-layer key contacts a lower-layer keyboard film through the pressure sensor, so as to activate circuit signal conduction. When the key is in conduction, a key resistance will change with pressure, and each key has a corresponding force-resistance change curve.

When providing key circuits of existing keyboards, various keys are connected to driving lines and induction lines in a way of facilitating layout and wiring, so that there is a large difference span in the force-resistance change curve of the key connected to the same induction line, and each induction line needs a large measurement range, thus affecting measurement accuracy of key resistance.

### SUMMARY

In view of this, embodiments of the present application aim at providing a key circuit capable of improving measurement accuracy.

In the first aspect, embodiments of the present application provide a key circuit, including: a plurality of keys, a plurality of driving lines, a plurality of induction lines and a control module, wherein the plurality of keys are divided into a plurality of regions according to parameters affecting force and resistance response, and the resistance of the keys in each region changes with pressure within the same range; each of the keys is connected to one of the driving lines and one of the induction lines, and keys in the same region are connected to the same induction line; and the plurality of driving lines and the plurality of induction lines are all connected to I/O interfaces of the control module, and the induction lines are configured to transmit acquired resistance information of corresponding keys to the control module, so as to output control information corresponding to the keys via the control module.

In the above implementation process, when designing the key circuit, the plurality of keys are divided into a plurality of regions according to the parameters affecting force and resistance response, and the keys in the same region are connected to the same induction line. Since the keys are divided according to the parameters affecting force and resistance response, resistance values of different keys connected to the same induction line may be made to change with pressure within a small range, so that measurement accuracy is improved. In addition, since the resistance values of different keys connected to the same induction line change within a small range, the same key may also be controlled by detecting magnitude of pressure acquired by the key, to implement different functions, thus increasing application scenarios of the keyboard.

In one embodiment, each of the driving lines is connected to a plurality of the keys, and the driving lines are configured to acquire driving signals sent by the control module and are controlled by the driving signals to be connected or disconnected.

In the above implementation process, by making each driving line to be connected to a plurality of keys, driving signals of the plurality of keys can be simultaneously controlled by one driving line, thus reducing configuration of the driving lines, and saving cost of the keyboard while simplifying structure of the key circuit.

In one embodiment, the key circuit further includes a plurality of bias resistors; and each bias resistor has one end connected with one of the induction lines, and the other end grounded.

In the above implementation process, by providing the bias resistors connected to the induction lines, the bias resistors can divide a voltage to divide a part of the electrical signals, further limiting the measurement range of the keys, and improving the measurement accuracy.

In one embodiment, a resistance value of each bias resistor is determined by a range of resistance value change of the keys connected to the same induction line as the bias resistor.

In the above implementation process, by setting that the resistance value of each bias resistor is determined by a range of resistance value change of the keys connected to the same induction line as the bias resistor, all of the measurement ranges of the electrical signals fed back to the control module by different keys connected to the same induction line can be limited to be within the same resistance measurement range, thus improving the measurement accuracy. In addition, since the bias resistor is directly connected to the induction line, there is no need to change an original key circuit and a circuit structure of the control module, and thus the circuit structure is simple and reconstruction cost is low.

In one embodiment, the key circuit further includes an amplifying module, wherein a non-inverting terminal of the amplifying module is connected to a reference potential, an inverting terminal of the amplifying module is connected to the induction line, and an output terminal of the amplifying module is connected to the I/O interface of the control module, wherein the amplifying module is configured to make potential of the plurality of induction lines equal, so as to block flow of current between the plurality of induction lines.

In the above implementation process, by providing the amplifying modules between the induction lines and the control module of the key circuit, the amplifying modules can be configured to make the plurality of induction lines have equal potential, so as to block flowing of the current between the plurality of induction lines, and when a plurality of keys on the same driving line which are connected to different induction lines are pressed down, no current flows between the different induction lines, so that a problem of ghost keys and a problem of crosstalk among the plurality of keys connected with the same driving line and different induction lines can be solved.

In one embodiment, the amplifying module includes: an operational amplifier and a gain resistor, wherein a non-inverting terminal of the operational amplifier is connected to a reference potential, an inverting terminal of the operational amplifier is connected to the induction line, and an output terminal of the operational amplifier is connected to the I/O interface of the control module; and one end of the gain resistor is connected to the inverting terminal of the operational amplifier, and the other end of the gain resistor is connected to the output terminal of the operational amplifier.

In the above implementation process, by providing the amplifying module to be in a structure of the operational amplifier plus the gain resistor, the operational amplifier can be in a state of a trans-impedance amplifier. Since an output current and an input voltage of the trans-impedance amplifier have a linear relationship therebetween, sensitivity and dynamic adjustment range of the amplifying module to the electrical signal can be improved. In addition, since the amplifying module only needs one operational amplifier and one resistor as components, the structure of the amplifying module can be simplified, so that the amplifying module is easy to manufacture and integrate, and meanwhile the cost and difficulty of the amplifying module can also be reduced.

In one embodiment, the parameters affecting force and resistance response include dimensions of keycaps of the keys; and the plurality of keys are divided into a plurality of regions according to sizes of the keycaps.

In the above implementation process, by dividing the keys into regions according to the sizes of keycaps of the keys, impact of keycap areas on the change of resistance value of the keys in the same region can be reduced, and the force-resistance curves of the keys in the same region are similar, so that the resistance values of different keys connected to the same induction line change with pressure within a small range, so that the measurement accuracy can be improved.

In one embodiment, the parameters affecting force and resistance response include dimensions of pressure sensors in the keys; and the plurality of keys are divided into a plurality of regions according to sizes of the pressure sensors.

In the above implementation process, by dividing the keys into regions according to the sizes of the pressure sensors, impact of areas of the pressure sensors on the change of resistance value of the keys in the same region can be reduced, and the force-resistance curves of the keys in the same region are similar, so that the resistance values of different keys connected to the same induction line change with pressure within a small range, so that the measurement accuracy can be improved.

In one embodiment, the parameters affecting force and resistance response include dimensions of domes in the keys; and the plurality of keys are divided into a plurality of regions according to heights of the domes or diameters of the domes.

In the above implementation process, by dividing the keys into regions according to the heights of the domes and/or the diameters of the domes, impact of the dimensions of the domes on the change of resistance value of the keys in the same region can be reduced, and the force-resistance curves of the keys in the same region are similar, so that the resistance values of different keys connected to the same induction line change with pressure within a small range, so that the measurement accuracy can be improved.

In one embodiment, each key includes a first electrode and a second electrode, wherein the first electrode is connected to the driving line, and the second electrode is connected to the induction line; and if a certain key is pressed down, current in a loop where the key is located flows from the driving line connected to the key into the first electrode of the key, flows into the induction line connected to the key through the first electrode of the key, the pressure sensor and the second electrode of the key in sequence, and then flows into the control module, so that the control module acquires resistance information of the key.

In the above implementation process, by connecting the driving line and the induction line to the first electrode and the second electrode of the key respectively, when the key is pressed down, the electrical signal in the driving line can be transmitted to the induction line through the first electrode and the second electrode, through contact between the first electrode and the second electrode, so as to acquire the resistance information of the key.

In order to make the above objectives, features and advantages of the present application more obvious and understandable, embodiments are particularly illustrated below in conjunction with drawings to make following detailed description.

### BRIEF DESCRIPTION OF DRAWINGS

In order to more clearly illustrate technical solutions of embodiments of the present application, drawings which need to be used in the embodiments will be briefly introduced below. It should be understood that the drawings merely show some embodiments of the present application, and thus should not be considered as limitation to the scope. Those ordinarily skilled in the art still could obtain other relevant drawings according to these drawings without using any inventive efforts.

FIG. 1 is a schematic view of a key circuit provided by embodiments of the present application;

FIG. 2 is a schematic view of force-resistance curves of 10 random keys provided by embodiments of the present application;

FIG. 3 is a schematic view of distribution of regions of keys provided by embodiments of the present application;

FIG. 4 is a schematic view of connection of keys in region #1 and region #2, after the keys are divided into regions, provided by embodiments of the present application;

FIG. 5 is a schematic view of connection of all keys, before the keys are divided into regions, provided by embodiments of the present application;

FIG. 6 is a schematic view of force-resistance curves of keys in a certain region, after the keys are divided into regions, provided by embodiments of the present application;

FIG. 7 is a schematic view of the key circuit provided with bias resistors according to the embodiments of the present application;

FIG. 8 is a schematic view of the key circuit provided with the bias resistors and amplifying modules according to the embodiments of the present application;

FIG. 9 is a structural schematic view of a dome provided by embodiments of the present application; and

FIG. 10 is a structural schematic view of a key provided by embodiments of the present application.

Illustration of reference signs: 110—key, 111—first electrode, 112—second electrode, 113—pressure sensor, 114—upper-layer key film, 115—lower-layer keyboard film, 120—driving line, 130—induction line, 140—control module, 150—bias resistor, 160—amplifying module, 161—operational amplifier, and 162—gain resistor.

### DETAILED DESCRIPTION OF EMBODIMENTS

Technical solutions in the embodiments of the present application will be described below in conjunction with the drawings in the embodiments of the present application.

In order to make the objectives, technical solutions and advantages of the embodiments of the present application clearer, the technical solutions in the embodiments of the present application will be described clearly and completely below in conjunction with the drawings in the embodiments of the present application. Apparently, the embodiments described are some but not all embodiments of the present application. Generally, components in the embodiments of the present application described and shown in the drawings herein may be arranged and designed in various different configurations.

Therefore, the following detailed description of the embodiments of the present application provided in the drawings is not intended to limit the claimed scope of the present application, but merely represents chosen embodiments of the present application. All of other embodiments obtained by those ordinarily skilled in the art based on the embodiments in the present application without using inventive efforts shall fall within the scope of protection of the present application.

It should be noted that like reference signs and letters represent like items in the following drawings, and thus, once a certain item is defined in one drawing, it is unnecessary to define the same in subsequent drawings. Meanwhile, in the description of the present application, the terms such as “first” and “second” are merely used for distinguishing the description, but should not be construed as indicating or implying importance in relativity.

In the description of the present application, it should be indicated that orientation or positional relationships indicated by the terms such as “upper”, “lower”, “inner”, and “outer” are based on orientation or positional relationships as shown in the drawings, or orientation or positional relationships of a product of the present application when being conventionally placed in use, merely for facilitating describing the present application and simplifying the description, rather than indicating or implying that related devices or elements have to be in a specific orientation or configured and operated in a specific orientation, and thus they should not be construed as limitation to the present application.

In the description of the present application, it should be further noted that, unless otherwise specifically regulated and defined, the terms “provide”, “install”, and “connect” should be understood in a broad sense, for example, a connection may be a fixed connection, a detachable connection, or an integrated connection; it may be a mechanical connection or an electrical connection; it may be direct joining or indirect joining through an intermediary, and it also may be inner communication between two elements. Specific meanings of the above terms in the present application could be understood by those ordinarily skilled in the art according to specific situations.

It should be noted that features in the embodiments of the present application may be combined with each other without conflict.

Keyboards are common input devices for electronic products and industrial equipment. A keyboard is usually provided with a plurality of keys which are different in structure, dimension and other aspects. Keys on current keyboards are usually correspondingly provided with one or two fixed functions, and corresponding function is implemented by one or more keys of the keys corresponding to the function. With the rapid development of computer technology, the keyboards are required to have more and more input functions. Existing keyboard functions are not able to meet the needs of development. In order to increase functions of keyboards, keys can be controlled to implement different functions by adding functions to each key, that is, by controlling pressure applied to the key. As resistance of the key changes with pressure, the resistance of the key can be divided into a plurality of different resistance ranges, and each resistance range is corresponding to a different function. When using the keyboard, by detecting the resistance of the key, a function currently needed to be realized by the keyboard is determined according to the resistance.

Upon long-term researches, the inventors of the present application found that, although the above mode can well solve the problem that the existing keyboard functions cannot meet the requirements of development, due to factors of the key such as keycap dimension, elastomer and shape of pressure sensor, the force-resistance response curve of each key is quite different. With the same degree of force, a range of the resistance has a large span, so that a measurement range of the key resistance is large, which affects measurement accuracy.

In view of this, the inventors of the present application propose a key circuit, which is divided into a plurality of regions according to parameters affecting force and resistance response, wherein the resistance of keys in each region changes with pressure within the same range, and keys in the same region are connected to the same induction line. Since the keys are divided according to the parameters affecting force and resistance response, resistance values of different keys connected to the same induction line change with pressure within a small range, so that measurement accuracy can be improved.

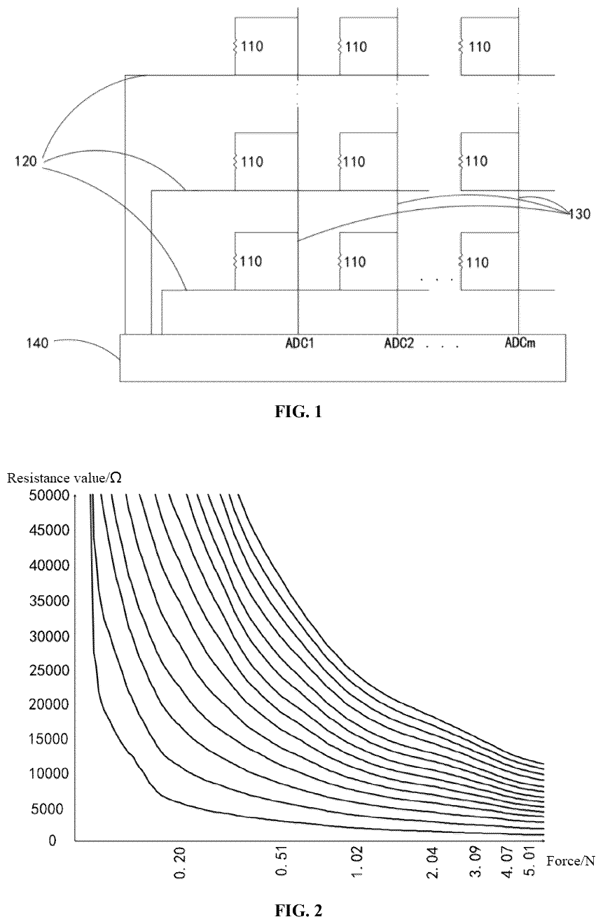

As shown in FIG. 1, a key circuit provided by embodiments of the present application includes: a plurality of keys 110, a plurality of driving lines 120, a plurality of induction lines 130 and a control module 140. The plurality of keys 110 are divided into a plurality of regions according to parameters affecting force and resistance response, and resistance of the keys 110 in each region changes with pressure within the same range.

In the above, each of the keys 110 is connected to one driving line 120 and one induction line 130, and the keys 110 in the same region are connected to the same induction line 130; and the plurality of driving lines 120 and the plurality of induction lines 130 are all connected to I/O interfaces of the control module 140.

The control module 140 herein includes a plurality of I/O interfaces (FIG. 1 shows ADC1 to ADC1m, m in total,), and the number of the I/O interfaces is greater than or equal to the total number of the induction lines 130 and the driving lines 120. Each driving line 120 is connected to one I/O interface of the control module 140, and each induction line 130 is also connected to one I/O interface of the control module 140. The driving lines 120 are configured to acquire driving signals (such as level signals and resistance signals) sent by the control module 140, and are controlled by the driving signals to be connected or disconnected. The induction lines 130 are configured to transmit acquired resistance information of corresponding keys 110 to the control module 140, so as to output control information corresponding to the keys 110 via the control module 140.

The above control module 140 may be a single chip microcomputer, an MCU, a CPLD, an ARM (Advanced RISC Machine), an FPGA (Field Programmable Gate Array), or the like, and the control module 140 may be selected according to a practical situation, which is not specifically limited in the present application. The control module 140 can be configured to output different driving signals through the I/O interfaces, so as to control different driving lines 120 to be in different states at the same moment.

For example, the control module 140 may be set with different driving signal control rules, so as to select a corresponding control rule according to a practical requirement to control an output electrical signal. For example, the control rule may be that each I/O interface is controlled in sequence to output a fixed level signal in time unit. The control rule may also be that the I/O interface connected to a scanned transverse branch is controlled according to a scanning result to output a fixed level signal or the like.

Exemplarily, when this control module 140 is in an operating state, this control module 140 outputs a high level to one driving line 120 at a certain moment, and outputs high resistance to other driving lines 120, so that only one driving line 120 is connected (i.e., in conduction) at this moment. If in this case, a certain key 110 connected to this connected driving line 120 is pressed down, the electrical signal of this driving line 120 may be input via this key 110 to the induction line 130 connected to this key 110, and input to the control module 140 via this induction line 130, and in turn this control module 140 outputs control information corresponding to the key 110.

It can be understood that, as dimensions of the keys 110, dimensions of the sensors, dimensions of films and the like are different, different keys 110 may generate different resistance values when being pressed down by the same degree of force. As shown in FIG. 2, FIG. 2 shows force-resistance curves of 10 random keys 110, where abscissa in FIG. 2 represents force, and ordinate represents resistance value. It can be seen from the force-resistance curves in FIG. 2 that when different keys 110 acquire the same degree of force, a range of resistance has a large span. For example, when the force is 1 N, minimum resistance of the keys 110 is 2000Ω, and maximum resistance of the keys 110 is 24000Ω.

If these keys 110 with larger difference in resistance values are all connected to the same induction line 130, when different keys 110 are pressed down by the same degree of force, electrical signals generated in the induction line 130 are have a large difference, so that a system for measuring this induction line 130 needs to be within a large measurement range. When the system for measuring this induction line 130 is within a large measurement range, accuracy of measurement of the keys 110 will be affected, and in turn it is hard to control the keys 110 to output different functions according to pressure information acquired by the keys 110.

If force-resistance changes of the keys 110 connected to the same induction line 130 are limited within a small range, measuring resistance of a measuring system corresponding to the induction line 130 may also be set within a small range, and then the keys 110 may be controlled to implement different functions by detecting pressure information acquired by different keys 110. For example, for the key 110 “left arrow”, if pressure information acquired by this key 110 is 1 N or less, the control function corresponding to this key 110 is: moving to the left. If the pressure information obtained by this key 110 is more than 1 N, the control function corresponding to this key 110 is: skipping to the left. Then, the same key 110 can implement different functions by applying different pressures.

When dividing the keys 110 into regions, the plurality of keys 110 may be divided into regions according to parameters affecting force and resistance response, so that the keys 110 having substantially similar force-resistance change curves are divided into the same region, and the keys 110 in the same region are connected to the same induction line 130.

It can be understood that each key 110 may include a keycap, a dome, a pressure sensor 113 and other structures. The parameters affecting force and resistance response herein include but are not limited to: dimension of the keycap of the key 110, dimension of the dome of the key 110, dimension of the sensor, etc.

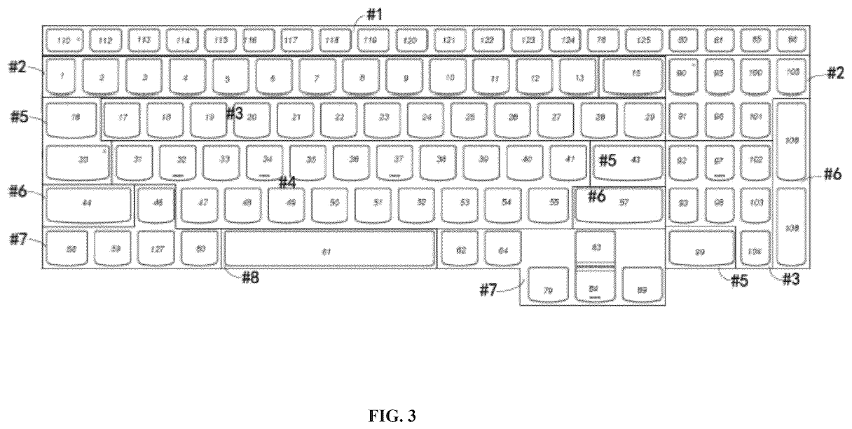

Exemplarily, if the keys are divided into regions according to dimensions of keycaps, as shown in FIG. 3, the keys on the keyboard can be divided into seven regions: regions #1, #2, #3, #4, #5, #6, and #7. In the above, #1 includes 20 keys in total, such as keys 110-86, #2 includes 20 keys in total, such as keys 1-13 and 90-101, #3 includes 20 keys in total, such as keys 17-29 and 92-104, #4 includes 20 keys in total, such as keys 31-41 and 47-55, #5 includes 4 keys in total, such as keys 16, 30, 43, and 99, #6 includes 4 keys such as keys 44, 57, 106, and 108, and #7 includes 10 keys in total, such as keys 46, 58-60, 62-64, 83, and 79-89.

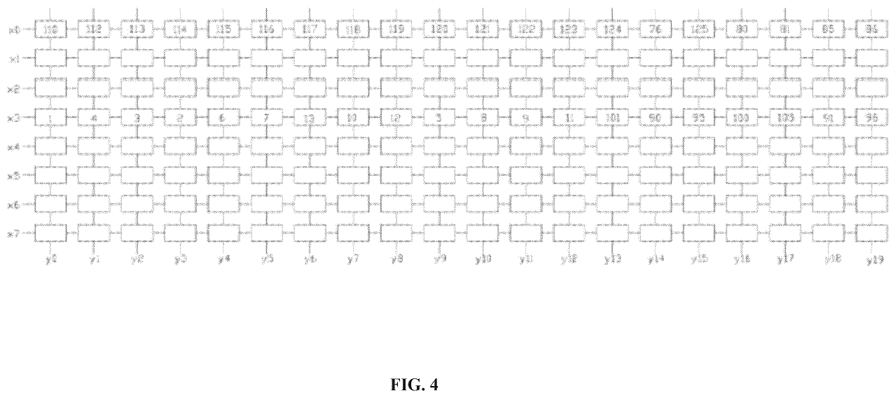

In the above, as shown in FIG. 4, 20 keys in #1 are all connected to the same induction line 130, 20 keys in #2 are all connected to the same induction line 130, 20 keys in #3 are all connected to the same induction line 130, 20 keys in #4 are all connected to the same induction line 130, 4 keys in #5 are all connected to the same induction line 130, 4 keys in #6 are all connected to the same induction line 130, and 10 keys in #7 are all connected to the same induction line 130. However, the 7 regions, #1, #2, #3, #4, #5, #6, and #7, are all connected to different induction lines 130. In the above, FIG. 4 shows that the keys in #1 are connected to an induction line 130x0, the keys in #2 are connected to an induction line X3, and all of the keys are connected to the driving lines 120y0-y19, respectively. Connection modes of the keys in other regions are not shown in FIG. 4.

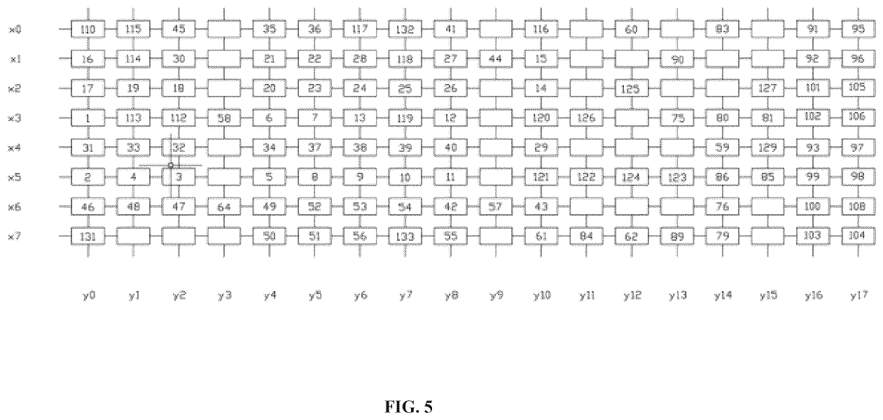

It can be understood that, if this key circuit is an improvement on the basis of an original key circuit, when connecting various keys, the driving line 120 and the induction line 130 correspondingly connected to each key can be modified as appropriate according to an initial connection condition of the key. Exemplarily, as shown in FIG. 5, FIG. 5 shows connection modes of various keys and corresponding induction lines 130 and driving lines 120 before the various keys in the keyboard are divided into regions. FIG. 4 shows connection modes of various keys and corresponding induction lines 130 and driving lines 120 after the various keys in the keyboard are divided into regions. By comparing FIG. 4 and FIG. 5, since a largest number of keys in the region #2 are connected to the induction line X3, all of the keys in the region #2 may be connected to the induction line X3. In the above, the keys 1, 6, 7, 13, 12 and so on are originally connected to the induction line X3, connections between the keys 1, 6, 7, 13, 12 and the induction line 130 and the driving line 120 remain unchanged. However, the keys where the driving lines 120 connected to the keys 4, 3, 10, 90, 100, 105 etc. correspondingly intersect with the induction line X3 are not keys in the region #2, and thus the keys 4, 3, 10, 90, 100 and 105 may be only modified to be connected with the induction line 130, that is, the keys 4, 3, 10, 90, 100 and 105 are connected to the induction line X3, and connections with corresponding driving lines 120 are not changed. For the other keys in the region #2, it is necessary to modify both correspondingly connected induction line 130 and correspondingly connected driving line 120.

If designing an entirely new keyboard circuit, the driving lines 120 and the induction lines 130 connected to various keys 110 may be provided according to distribution of the keys 110 on the keyboard, in accordance with various factors such as wiring convenience, wiring cost and aesthetics of wire layout. Specific connection modes of various keys 110 in the key circuit may be adjusted according to a practical situation, which is not specifically limited in the present application.

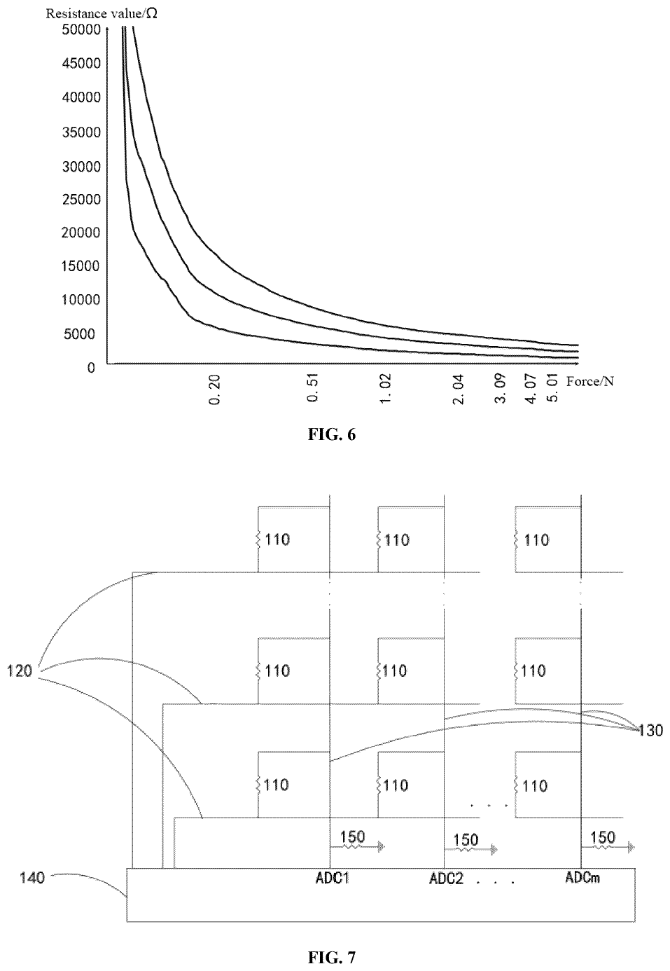

It should be understood that, if the keys 110 in FIG. 2 are divided into regions, in the above, the keys 110 in one region are as shown in FIG. 6 (FIG. 6 shows force-resistance curves of 3 keys 110 in FIG. 2). When pressure acquired by the key 110 is extremely small, it may be determined that this key 110 is not triggered. Therefore, a curve of a pressure smaller than a certain value may be ignored. If the pressure greater than 0.5 N is considered as the key being triggered herein, it can be seen by checking FIG. 6 that the resistance range of the keys 110 divided into regions is about 900-8000Ω. Specifically, in the above, a dynamic resistance range of one key 110 is 3000-7800Ω, a dynamic resistance range of one key 110 is 2000-5000Ω, and a dynamic resistance range of one key 110 is 900-2800Ω. Apparently, the resistance change range after being divided into regions is much smaller than that before being divided into regions.

In the above implementation process, when designing the key circuit, the plurality of keys 110 are divided into a plurality of regions according to the parameters affecting force and resistance response, and the keys 110 in the same region are connected to the same induction line 130. Since the keys 110 are divided according to the parameters affecting force and resistance response, resistance values of different keys 110 connected to the same induction line 130 may be made to change with pressure within a small range, so that measurement accuracy is improved. In addition, since the resistance values of different keys 110 connected to the same induction line 130 change within a small range, the same key 110 may also be controlled to implement different functions by detecting magnitude of pressure acquired by the key 110, thus increasing application scenarios of the keyboard.

In a possible implementation, each driving line 120 is connected to a plurality of keys 110.

In the above, the data of keys 110 connected to each driving line 120 may be determined according to the number of regions of the keys 110 obtained by dividing, and each driving line 120 may be connected to one key 110 in each region. For example, if the keys 110 are divided into five regions, each driving line 120 may be connected to five keys 110. If the keys 110 are divided into seven regions, each driving line 120 may be connected to seven keys 110.

The number of the driving lines 120 herein may be determined according to the number of keys 110 in the region with the largest number of keys 110 after being divided into regions. For example, as shown in FIG. 3, the number of keys 110 in #1, #2, #3 and #4 is the largest, each having 20 keys 110, and thus the number of the driving lines 120 may also be set to be 20.

The plurality of driving lines 120 and induction lines 130 above form a matrix circuit, a keyboard is provided at intersection of each driving line 120 and each induction line 130, and the keyboard is respectively connected to the intersected driving line 120 and induction line 130.

In the above implementation process, by making each driving line 120 connected to a plurality of keys 110, driving signals of the plurality of keys 110 may be simultaneously controlled by one driving line 120, thus reducing configuration of the driving lines 120, and saving cost of the keyboard while simplifying structure of the key circuit.

In a possible implementation, as shown in FIG. 7, the key circuit further includes: a plurality of bias resistors 150.

In the above, each bias resistor 150 has one end connected with one induction line 130, and the other end grounded.

Herein, resistance values of the plurality of bias resistors 150 may be the same, different, or partially the same. The bias resistor 150 may be one or more of resistor with a fixed resistance value, adjustable resistor and digital potentiometer. A specific structure and a resistance value of the gain resistor 162 may be adjusted according to a practical situation, which is not specifically limited in the present application.

The bias resistors 150 herein are configured to limit the measurement ranges of the keys 110 and improve the measurement accuracy. It should be understood that one end of the bias resistor 150 is connected to the induction line 130, and when the induction line 130 transmits the acquired electrical signal to the amplifying module 160, the voltage may be divided by the bias resistor 150 to divide a part of the electrical signal, and then the electrical signal input into the control module 140 is within the measurement range corresponding to the induction line 130.

In the above implementation process, the bias resistors 150 are provided and the bias resistors 150 are connected to the induction lines 130, such that the bias resistors 150 can divide the voltage to divide a part of the electrical signals, and thus further limit the measurement range of the keys 110 and improve the measurement accuracy.

In a possible implementation, the resistance value of each bias resistor 150 is determined by a range of resistance value change of the keys 110 connected to the same induction line 130 as the bias resistor 150.

It can be understood that the force-resistance curves of the keys 110 in different regions have a large difference, and then when the control module 140 measures the electrical signals of different induction lines 130, corresponding measurement ranges have a large difference. If the measurement is performed directly, different measurement ranges, corresponding measurement rules and the like need to be set for different induction lines 130 respectively, which is troublesome to implement, makes the structure of the key circuit more complex, and also may have a high cost.

By connecting one bias resistor 150 to each induction line 130, the bias resistor 150 may divide voltage, thereby limiting the range of the electrical signal transmitted into the control module 140. In addition, by analyzing situation of the force-resistance curve of the keys 110 in each region, corresponding bias resistors 150 may also be provided according to differences between the force-resistance curves of the keys 110 in the individual regions, so that after the electrical signal in each induction line 130 is divided by corresponding bias resistor 150, the electrical signal input into the control module 140 is within the same measurement range.

In one embodiment, the same bias resistor 150 may be provided to be connected with the induction line 130 corresponding to regions with similar force-resistance curves, so that the electrical signals fed back by these keys 110 with similar force-resistance curves are close.

Exemplarily, as shown in FIG. 3, the force-resistance curves corresponding to the keys 110 in the regions #3 and #4 are similar, and then the same bias resistor 150 may be provided to be connected with the induction line 130 corresponding to the regions #3 and #4, so that the electrical signals fed back by the keys 110 in the regions #3 and #4 are close.

In the above implementation process, by setting that the resistance value of each bias resistor 150 is determined by a range of resistance value change of the keys 110 connected to the same induction line 130 as the bias resistor 150, all of the measurement ranges of the electrical signals fed back to the control module 140 by different keys 110 connected to the same induction line 130 may be limited to be within the same resistance measurement range, thus improving the measurement accuracy. In addition, since the bias resistor 150 is directly connected to the induction line 130, there is no need to change an original key circuit and a circuit structure of the control module 140, and thus the circuit structure is simple and reconstruction cost is low.

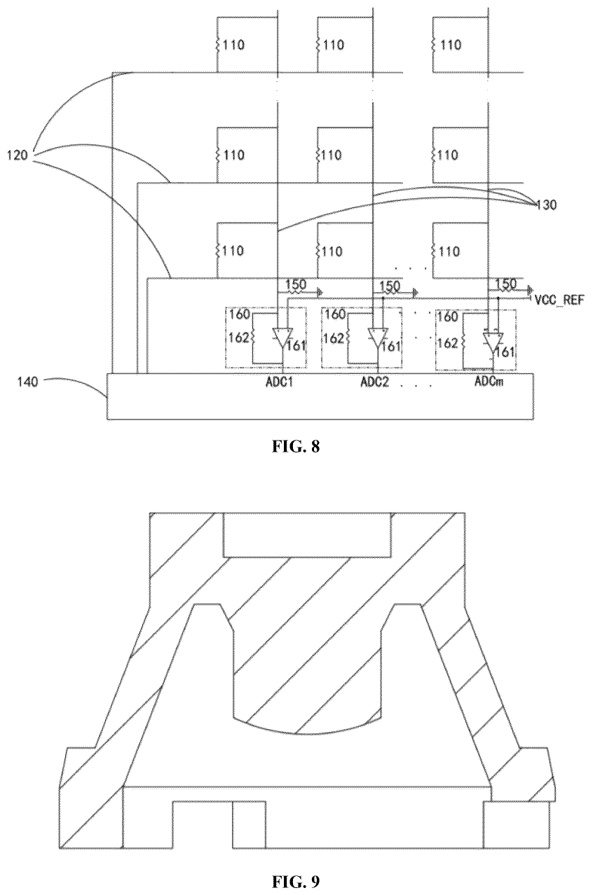

In a possible implementation, as shown in FIG. 8, the key circuit further includes the amplifying module 160.

In the above, a non-inverting terminal of the amplifying module 160 is connected to a reference potential, an inverting terminal of the amplifying module 160 is connected to the induction line 130, and an output terminal of the amplifying module 160 is connected to the I/O interface of the control module 140.

There are also a plurality of amplifying modules 160 herein, and the number of the amplifying modules 160 is equal to that of the induction lines 130. The amplifying modules 160 are configured to make potential of the plurality of induction lines 130 equal, so as to block flowing of current between the plurality of induction lines 130.

In one embodiment, each driving line 120 is connected to one I/O interface of the control module 140. Each induction line 130 is connected to the inverting terminal of one amplifying module 160, non-inverting terminals of the plurality of amplifying modules 160 are all connected to the same reference potential, and the output terminal of each amplifying module 160 is connected to one I/O interface of the control module 140.

The above amplifying module 160 may be an operational amplifier 161, or an amplifying circuit formed by electronic components such as triodes, diodes, and resistors. A specific structure of the amplifying module 160 may be selected according to a practical situation. The amplifying module 160 has characteristics of the operational amplifier 161, that is, when voltages at the non-inverting terminal and the inverting terminal of the amplifying module 160 are equal, the non-inverting terminal and the inverting terminal thereof are “virtually short-circuited”.

A voltage input by the above reference potential to the non-inverting terminal of the amplifying module 160 is equal to a voltage input by the induction line 130 to the inverting terminal of the amplifying module 160, so that when the induction line 130 inputs current to the inverting terminal of the amplifying module 160 connected thereto, voltages at the inverting terminal of the amplifying module 160 and the non-inverting terminal of the amplifying module 160 are substantially equal, thus making the amplifying module 160 be in a virtual-short-circuit state. The reference potential may be provided by a power supply chip, a resistance divider or the like.

When a plurality of induction lines 130 in the key circuit all input current to the inverting terminals of corresponding amplifying modules 160, the corresponding plurality of amplifying modules 160 are all in the virtual-short-circuit state. In this case, voltages at the inverting terminals of the plurality of amplifying modules 160 are all equal to voltages at the non-inverting terminals of the plurality of amplifying modules 160, and equal to the reference potential. That is, the voltages at the inverting terminals of the plurality of amplifying modules 160 are all equal, so that voltages at a plurality of corresponding longitudinal branches are equal, and no current flows between the plurality of longitudinal branches.

In the above implementation process, by providing the amplifying modules 160 between the induction lines 130 and the control module 140 of the key circuit, the amplifying modules 160 may be configured to make the plurality of induction lines 130 have equal potential, so as to block flowing of the current between the plurality of induction lines 130, and when a plurality of keys 110 on the same driving line 120 which are connected to different induction lines 130 are pressed down, no current may flow between the different induction lines 130, so that a problem of ghost keys and a problem of crosstalk among the plurality of keys 110 connected with the same driving line 120 and different induction lines 130 can be solved.

In a possible implementation, the amplifying module 160 includes: an operational amplifier 161 and a gain resistor 162.

In the above, a non-inverting terminal of the operational amplifier 161 is connected to a reference potential, an inverting terminal of the operational amplifier 161 is connected to the induction line 130, and an output terminal of the operational amplifier 161 is connected to the I/O interface of the control module 140; and one end of the gain resistor 162 is connected to the inverting terminal of the operational amplifier 161, and the other end of the gain resistor 162 is connected to the output terminal of the operational amplifier 161.

It should be understood that when there are a plurality of amplifying modules 160, a plurality of operational amplifiers 161 and a plurality of gain resistors 162 are also correspondingly provided.

The gain resistor 162 herein may be one or more of resistor with a fixed resistance value, adjustable resistor and digital potentiometer. A specific structure of the gain resistors 162 may be adjusted according to a practical situation, which is not specifically limited in the present application.

It can be understood that by adding the gain resistor 162 between the non-inverting terminal and the output terminal of the operational amplifier 161, and providing the reference resistor at the non-inverting terminal of the operational amplifier 161, the operational amplifier 161 may be made in a state of a trans-impedance amplifier.

The trans-impedance amplifier may convert an input voltage signal into a current signal, that is, when an input voltage signal is applied to a resistor, the resistor may generate current and the current is amplified by the operational amplifier 161. In the trans-impedance amplifier, a negative feedback loop of the operational amplifier 161 is established by a resistor; therefore, when an input voltage signal changes, the current on the resistor may also correspondingly change, so that an output current is adjusted. Because the output current and an input voltage thereof have a linear relationship therebetween, high sensitivity and dynamic range may be provided. In addition, since the trans-impedance amplifier only needs one operational amplifier 161 and one resistor as components, the cost is relatively low, and manufacturing and integrating are easy.

In one embodiment, the above electrical signal may be converted into an ADC value through this key circuit, where a magnitude of the ADC value is related to the resistance value of the key 110, the bias resistor 150, the gain resistor 162, the reference potential, and so on. When the bias resistor 150, the gain resistor 162, the reference potential and so on corresponding to each induction line 130 are determined, the resistance value of corresponding key 110 may be calculated.

In the above implementation process, by providing the amplifying module 160 to be in a structure of the operational amplifier 161 plus the gain resistor 162, the operational amplifier 161 may be made in a state of a trans-impedance amplifier. Since an output current and an input voltage of the trans-impedance amplifier have a linear relationship therebetween, sensitivity and dynamic adjustment range of the amplifying module 160 to the electrical signal may be improved. In addition, since the amplifying module 160 only needs one operational amplifier 161 and one resistor as components, the structure of the amplifying module 160 may be simplified, so that the amplifying module 160 is easy to manufacture and integrate, and meanwhile the cost and difficulty of the amplifying module 160 may also be reduced.

In a possible implementation, the parameters affecting force and resistance response may include: various parameters, such as dimensions of keycaps, dimensions of pressure sensors 113 and dimensions of domes of keys 110.

Correspondingly, the keys 110 may be divided into regions in many modes, including but not limited to the following.

Mode 1: a plurality of keys 110 are divided into a plurality of regions according to sizes of the keycaps.

The sizes of the keycaps herein are areas of the keycaps. It should be understood that when the keys 110 are divided into regions according to the sizes of the keycaps, the keys 110 with the same size of keycaps may be divided into one region, and the keys 110 in this region have similar pressure-resistance curves.

In one embodiment, when there are a large number of keys 110 with the same size of keycaps, the plurality of keys 110 with the same size of keycaps may be divided into a plurality of regions. That is, the sizes of keycaps of the keys 110 in different regions may be the same or different. For example, the sizes of keycaps of the keys 110 in the regions #3 and #4 in FIG. 3 are the same, and the sizes of keycaps of the keys 110 in the regions #3 and #6 in FIG. 3 are different.

In the above implementation process, by dividing the keys 110 into regions according to the sizes of keycaps of the keys 110, impact of keycap areas on the change of resistance value of the keys 110 in the same region can be reduced, and the force-resistance curves of the keys 110 in the same region are similar, so that the resistance values of different keys 110 connected to the same induction line 130 change with pressure within a small range, so that the measurement accuracy can be improved.

Mode 2: a plurality of keys 110 are divided into a plurality of regions according to sizes of the pressure sensors 113.

It can be understood that each key 110 is provided with the pressure sensor 113 therebelow, and the pressure sensors 113 corresponding to the individual keys 110 may be the same or different. When the pressure sensors 113 corresponding to the keys 110 have different sizes, the keys 110 may be divided into regions according to the sizes of the pressure sensors 113. The pressure sensors 113 are configured to acquire pressure information of corresponding keys 110 when being pressed down, and different pressure information is corresponding to different sensor resistance value.

The sizes of the pressure sensors 113 herein are areas of the pressure sensors 113. It should be understood that when the keys 110 are divided into regions according to the sizes of the pressure sensors 113, the keys 110 with the pressure sensors 113 of same size may be divided into one region, and the keys 110 in this region have similar pressure-resistance curves.

In one embodiment, when there are a large number of keys 110 with the pressure sensors 113 of the same size, the plurality of keys 110 with the pressure sensors 113 of the same size may be divided into a plurality of regions. That is, the sizes of pressure sensors 113 of the keys 110 in different regions may be the same or different.

In the above implementation process, by dividing the keys 110 into regions according to the sizes of the pressure sensors 113, impact of areas of the pressure sensors 113 on the change of resistance value of the keys 110 in the same region can be reduced, and the force-resistance curves of the keys 110 in the same region are similar, so that the resistance values of different keys 110 connected to the same induction line 130 change with pressure within a small range, so that the measurement accuracy can be improved.

Mode 3: a plurality of keys 110 are divided into a plurality of regions according to heights of the domes and/or diameters of the domes.

The dome herein is a triggering switch between a main board and the key 110. Besides being used as a switch, the dome also has a function of enhancing hand feeling. The dome may be structured in a circular shape, an oval shape, an irregular quadrilateral shape, etc., and a specific structure of the dome may be selected according to a practical situation.

As shown in FIG. 9, FIG. 9 shows a structure of the dome, wherein the dome includes structural parameters in two aspects of height and diameter. Different domes may have different heights and/or diameters, and different heights or different diameters of the domes may lead to different force-resistance response curves of corresponding pressure sensors 113. Therefore, the keys 110 can also be divided into regions by the dimensions of the domes.

When the keys 110 are divided into regions by the dimensions of the domes, the keys 110 may be divided into regions only by the heights of the domes, or the keys 110 may be divided into regions by the diameters of the domes, or the keys 110 may be divided into regions by a combination of heights of the domes and diameters of the domes. A specific mode of dividing the keys 110 by the dimensions of the domes may be adjusted according to a practical situation, which is not specifically limited in the present application.

It should be understood that the mode 1, mode 2 and mode 3 above are merely exemplary, and the keys 110 may also be divided into regions parameters other than the parameters in the mode 1, mode 2 and mode 3 above. Certainly, the dividing may also be performed by combining any two or more of the dividing modes of the mode 1, mode 2 and mode 3 above. For example, the keys 110 may also be divided into regions by a combination of the mode 1 and the mode 2, that is, divided into regions by combining the sizes of the keycaps and the sizes of the pressure sensors 113. The dividing mode of the keys 110 may be selected according to a practical situation.

In the above implementation process, by dividing the keys 110 into regions according to the heights of the domes and/or the diameters of the domes, impact of the dimensions of the domes on the change of resistance value of the keys 110 in the same region can be reduced, and the force-resistance curves of the keys 110 in the same region are similar, so that the resistance values of different keys 110 connected to the same induction line 130 change with pressure within a small range, so that the measurement accuracy can be improved.

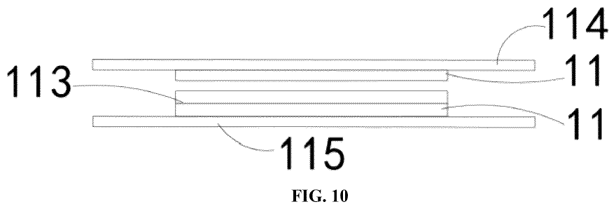

In a possible implementation, as shown in FIG. 10, each key 110 includes a first electrode 111 and a second electrode 112.

In the above, the first electrode 111 is connected to the driving line 120, and the second electrode 112 is connected to the induction line 130.

As shown in FIG. 10, the key 110 further includes: an upper-layer key film 114, an intermediate insulating film (not shown in the drawing) and a lower-layer keyboard film 115, and the pressure sensor 113 is further provided at the key 110 position of the lower-layer keyboard film 115. When the keycap is pressed down, an upper-layer key 110 position is in contact with the lower-layer keyboard film 115 via the pressure sensor 113, so as to activate signal conduction of the key circuit.

The first electrode 111 herein may be provided on the upper-layer key film 114, and the second electrode 112 may be provided on the lower-layer keyboard film 115. The first electrode 111 and the second electrode 112 may be both provided on the upper-layer key film 114. The first electrode 111 and the second electrode 112 also may be both provided on the lower-layer keyboard film 115, etc. An arrangement mode of the first electrode 111 and the second electrode 112 may be adjusted according to a practical situation.

It can be understood that if a certain key 110 is pressed down, current in a loop where the key is located flows from the driving line 120 connected to the key into the first electrode 111 of the key, flows into the induction line 130 connected to the key, through the first electrode 111 of the key, the pressure sensor 113 and the second electrode 112 of the key in sequence, and then flows into the control module 140, so that the control module 140 acquires resistance information of the key 110. In the above implementation process, by connecting the driving line 120 and the induction line 130 to the first electrode 111 and the second electrode 112 of the key 110 respectively, and when the key 110 is pressed down, the electrical signal in the driving line 120 may be transmitted through contact between the first electrode 111 and the second electrode 112, to the induction line 130 through the first electrode 111 and the second electrode 112, so as to acquire the resistance information of the key 110.

The above-mentioned are merely preferred embodiments of the present application, but are not used to limit the present application. For those skilled in the art, various modifications and changes could be made to the present application. Any modifications, equivalent substitutions, improvements and so on made within the spirit and principle of the present application should be covered within the scope of protection of the present application. It should be noted that like reference signs and letters represent like items in the following drawings, and thus, once a certain item is defined in one drawing, it is unnecessary to further define the same in subsequent drawings.

The above-mentioned are merely embodiments of the present application, but the scope of protection of the present application is not limited thereto, and any variation or substitution that may be easily conceived by those skilled in the art within the technical scope disclosed in the present application should fall within the scope of protection of the present application. Therefore, the scope of protection of the present application should be determined by the scope of protection of the claims.

What is claimed is:

1. A key circuit, characterized by comprising: a plurality of keys, a plurality of driving lines, a plurality of induction lines and a control module, wherein the plurality of keys are divided into a plurality of regions according to parameters affecting force and resistance response, and resistance of the keys in each of the regions changes with pressure within a same range;
each of the keys is connected to one of the driving lines and one of the induction lines, and keys in the same region are connected to a same induction line; and
the plurality of driving lines and the plurality of induction lines are all connected to I/O interfaces of the control module, and the induction lines are configured to transmit acquired resistance information of corresponding keys to the control module, so as to output control information corresponding to the keys via the control module.

2. The key circuit according to claim 1, characterized in that each of the driving lines is connected to a plurality of the keys, and the driving lines are configured to acquire driving signals sent by the control module and are controlled by the driving signals to be connected or disconnected.

3. The key circuit according to claim 1, characterized in that the key circuit further comprises a plurality of bias resistors, wherein
each of the bias resistors has one end connected with one of the induction lines, and the other end grounded.

4. The key circuit according to claim 3, characterized in that a resistance value of the each bias resistor is determined by a range of resistance value change of the keys connected to the same induction line as the bias resistor.

5. The key circuit according to claim 1, characterized in that the key circuit further comprises an amplifying module, wherein
a non-inverting terminal of the amplifying module is connected to a reference potential, an inverting terminal of the amplifying module is connected to the induction line, and an output terminal of the amplifying module is connected to the I/O interface of the control module; and
wherein the amplifying module is configured to make potential of the plurality of induction lines equal, so as to block flowing of current between the plurality of induction lines.

6. The key circuit according to claim 5, characterized in that the amplifying module comprises: an operational amplifier and a gain resistor, wherein
a non-inverting terminal of the operational amplifier is connected to the reference potential, an inverting terminal of the operational amplifier is connected to the induction line, and an output terminal of the operational amplifier is connected to the I/O interface of the control module; and
one end of the gain resistor is connected to the inverting terminal of the operational amplifier, and the other end of the gain resistor is connected to the output terminal of the operational amplifier.

7. The key circuit according to claim 1, characterized in that the parameters affecting force and resistance response comprise dimensions of keycaps of the keys; and
the plurality of keys are divided into the plurality of regions according to sizes of the keycaps.

8. The key circuit according to claim 1, characterized in that the parameters affecting force and resistance response comprise dimensions of pressure sensors in the keys; and
the plurality of keys are divided into the plurality of regions according to sizes of the pressure sensors.

9. The key circuit according to claim 1, characterized in that the parameters affecting force and resistance response comprise dimensions of domes in the keys; and
the plurality of keys are divided into the plurality of regions according to heights of the domes and/or diameters of the domes.

10. The key circuit according to claim 1, characterized in that each of the keys comprises a first electrode and a second electrode, wherein
the first electrode is connected to the driving line, and the second electrode is connected to the induction line; and
if a certain key is pressed down, current in a loop where the key is located flows from the driving line connected to the key into the first electrode of the key, flows into the induction line connected to the key through the first electrode of the key, a pressure sensor and the second electrode of the key in sequence, and then flows into the control module, so that the control module acquires resistance information of the key.
